(19) United States
(12) Patent Application Publication
(10) Pub. No.: US 2024/0420908 A1
(43) Pub. Date: Dec. 19, 2024

(54) RELAY CIRCUIT AND ELECTRICAL CONNECTION APPARATUS

(71) Applicant: Kabushiki Kaisha Nihon Micronics, Tokyo (JP)

(72) Inventors: Souichi KANOSUE, Oita (JP); Masataka KIMOTO, Oita (JP); Toshihisa KADOWAKI, Oita (JP); Shin SAKIYAMA, Oita (JP)

(21) Appl. No.: 18/740,475

(22) Filed: Jun. 11, 2024

(30) Foreign Application Priority Data
Jun. 13, 2023 (JP) 2023-097008

(51) Int. Cl. H01H 50/14; H05K 7/02

(52) U.S. Cl. CPC H01H 50/14; H05K 7/026

(57) ABSTRACT

An electrical connection apparatus includes terminals for inspection, a wiring board, and a relay circuit. The wiring board includes first electrodes electrically connected to any one of the terminals for inspection, connecting wiring connected to any one of the first electrodes, and second electrodes electrically connected to any one of the first electrodes via the connecting wiring. The relay circuit is connected to first wiring and second wiring. The relay circuit includes a common terminal, a first wiring terminal connected to the first wiring, a second wiring terminal connected to the second wiring, and a first inspection terminal and a second inspection terminal electrically connected to an inspection device. The relay circuit selectively connects the first wiring terminal to either the common terminal or the first inspection terminal, and selectively connects the second wiring terminal to either the common terminal or the second inspection terminal.

### CROSS-REFERENCE TO RELATED APPLICATIONS

The present application is based on and claims the benefit of priority from the prior Japanese Patent Application No. 2023-097008, filed on Jun. 13, 2023, the entire contents of which are incorporated by reference herein.

### TECHNICAL FIELD

The present invention relates to a relay circuit and an electrical connection apparatus used for inspecting electrical characteristics of an object to be inspected.

### BACKGROUND

To measure electrical characteristics of an object to be inspected, such as an integrated circuit, an electrical connection apparatus having a terminal for inspection in contact with the object to be inspected is used. In the measurement using the electrical connection apparatus, the object to be inspected is electrically connected to an inspection device such as a tester via the terminal for inspection.

In order to inspect the characteristics of the object to be inspected, whether an output unit and an input unit of the object to be inspected are functioning may be inspected by inputting a signal output from an output terminal of the object to be inspected to an input terminal of the object to be inspected. For this purpose, an electrical connection apparatus is used which can constitute a circuit (hereinafter also referred to as a “loopback circuit”) for electrically connecting the output terminal and the input terminal of the object to be inspected.

### SUMMARY OF THE INVENTION

In order to measure characteristics of an object to be inspected with high accuracy, it is important to reduce the loss and noise of a loopback circuit through which a signal propagates. An object of the present invention is to provide a relay circuit and an electrical connection apparatus capable of reducing the loss and noise of a loopback circuit.

An electrical connection apparatus according to one aspect of the present invention includes a plurality of terminals for inspection, a wiring board, and a relay circuit. The wiring board includes a plurality of first electrodes each of which is electrically connected to any one of the terminals for inspection, a plurality of connecting wiring each of which is connected to any one of the first electrodes, and a plurality of second electrodes each of which is electrically connected to any one of the first electrodes via the connecting wiring. The relay circuit is connected to first wiring and second wiring, each of which is electrically connected to either one of first electrodes different from each other. The relay circuit includes a common terminal, a first wiring terminal connected to the first wiring, a second wiring terminal connected to the second wiring, and a first inspection terminal and a second inspection terminal that can be electrically connected to an inspection device. The relay circuit selectively connects the first wiring terminal to either the common terminal or the first inspection terminal, and the relay circuit selectively connects the second wiring terminal to either the common terminal or the second inspection terminal.

### BRIEF DESCRIPTION OF THE DRAWINGS

FIG. 1 is a schematic view showing a configuration of an electrical connection apparatus according to a first embodiment.

FIG. 2 is a schematic view showing a configuration of a relay circuit of the electrical connection apparatus according to the first embodiment.

FIG. 3 is a schematic view showing a first connection state of the electrical connection apparatus according to the first embodiment.

FIG. 4 is a schematic view showing a second connection state of the electrical connection apparatus according to the first embodiment.

FIG. 5 is a schematic view showing a configuration of a capacitor included in the relay circuit of the electrical connection apparatus according to the first embodiment.

FIG. 6A is a schematic side view showing the configuration of the relay circuit of the electrical connection apparatus according to the first embodiment.

FIG. 6B is a schematic cross-sectional view showing the configuration of the relay circuit of the electrical connection apparatus according to the first embodiment.

FIG. 6C is a schematic front view showing the configuration of the relay circuit of the electrical connection apparatus according to the first embodiment.

FIG. 7A is a schematic side view showing a first connection state of the relay circuit shown in FIG. 6A.

FIG. 7B is a schematic cross-sectional view showing a first connection state of the relay circuit shown in FIG. 6B.

FIG. 7C is a schematic front view showing a first connection state of the relay circuit shown in FIG. 6C.

FIG. 8A is a schematic side view showing a second connection state of the relay circuit shown in FIG. 6A.

FIG. 8B is a schematic cross-sectional view showing a second connection state of the relay circuit shown in FIG. 6B.

FIG. 8C is a schematic front view showing a second connection state of the relay circuit shown in FIG. 6C.

FIG. 9A is a schematic view showing a first connection state of a relay circuit of a comparative example.

FIG. 9B is a schematic view showing a second connection state of the relay circuit of the comparative example.

FIG. 10A is a schematic side view showing a configuration of a relay circuit of an electrical connection apparatus according to a second embodiment.

FIG. 10B is a schematic cross-sectional view showing the configuration of the relay circuit of the electrical connection apparatus according to the second embodiment.

FIG. 10C is a schematic front view showing the configuration of the relay circuit of the electrical connection apparatus according to the second embodiment.

FIG. 11A is a schematic side view showing a first connection state of the relay circuit shown in FIG. 10A.

FIG. 11B is a schematic cross-sectional view showing a first connection state of the relay circuit shown in FIG. 10B.

FIG. 11C is a schematic front view showing a first connection state of the relay circuit shown in FIG. 10C.

### DETAILED DESCRIPTION

Embodiments of the present invention will be described with reference to the drawings. In the description of the drawings below, the same or similar parts are denoted with the same or similar reference numerals. However, it should be noted that the drawings are schematically shown and the ratios of the thickness of each portion and the like are different from those in reality. Further, it is needless to say that the drawings include portions where the relationships and ratios of dimensions are different between drawings. The following embodiments exemplify an apparatus and a method for embodying the technical concept of the present invention, and the embodiments of the present invention do not specify the material, shape, structure, arrangement, and the like of components to the following.

### First Embodiment

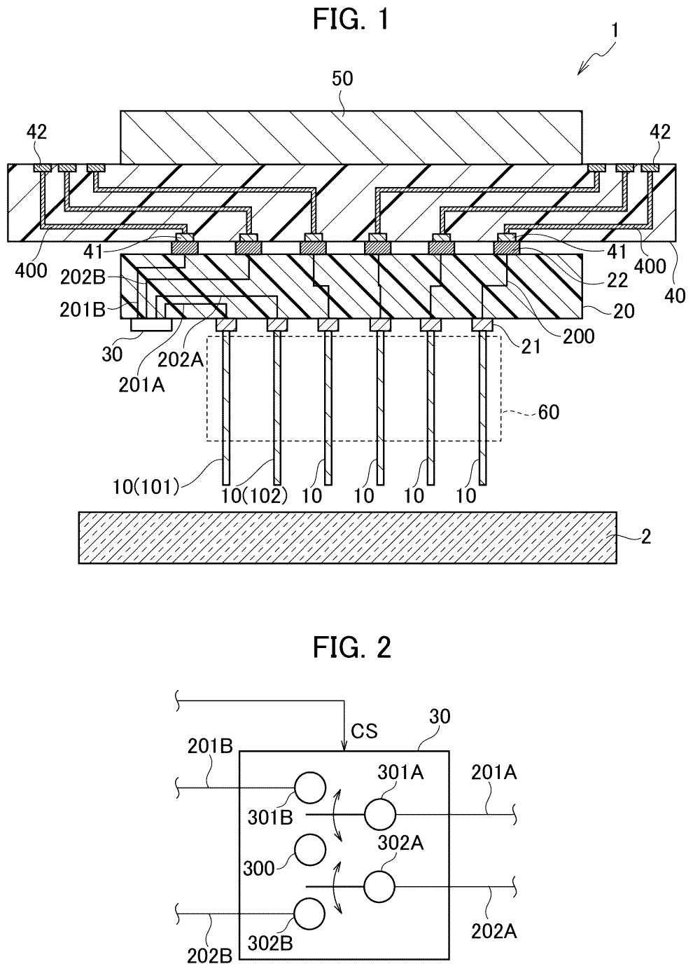

An electrical connection apparatus 1 according to a first embodiment shown in FIG. 1 is used for inspecting an object 2 to be inspected. The electrical connection apparatus 1 includes a plurality of probes 10 that come into contact with the object 2 to be inspected when the object 2 to be inspected is inspected, a wiring board 20 connected to the probes 10, and a relay circuit 30 arranged on the wiring board 20. The electrical connection apparatus 1 further includes a printed board 40 laminated on the wiring board 20 and a stiffener 50 laminated on the printed board 40.

One end (hereinafter also referred to as a “proximal end”) of each of the probes 10 is connected to the wiring board 20. During the inspection of the object 2 to be inspected, the other end (hereinafter also referred to as a “tip”) of each of the probes 10 contacts a signal terminal (not shown) of the object 2 to be inspected. The plurality of probes 10 function as a plurality of terminals for inspection for electrically connecting the object 2 to be inspected and an inspection device. FIG. 1 shows a state in which the probes 10 and the object 2 to be inspected are separated. The probes 10 may be supported by a probe head 60 through which the probes 10 pass. The probe head 60 may be a housing having an internal space. The probe head 60 are fixed to the wiring board 20, for example.

As shown in FIG. 1, the wiring board 20 includes a plurality of first electrodes 21 each of which is electrically connected to any one of the plurality of probes 10 and a plurality of second electrodes 22 each of which is electrically connected to any one of the first electrodes 21. The second electrodes 22 are electrically connected to the first electrodes 21 via a plurality of connecting wiring 200 each of which is electrically connected to any one of the first electrodes 21. The first electrodes 21 are connected to proximal ends of the probes 10. The connecting wiring 200 may be internal wiring arranged inside the wiring board 20, for example. A multilayer wiring board such as Multi-Layer Organic (MLO) or Multi-Layer Ceramic (MLC) may be used for the wiring board 20, for example.

The printed board 40 includes wiring patterns 400 for electrically connecting the second electrodes 22 of the wiring board 20 and the inspection device. First ends 41 of the wiring patterns 400 disposed inside and on a surface of the printed board 40 are connected to the second electrodes 22 of the wiring board 20, and second ends 42 of the wiring patterns 400 are electrically connected to the inspection device, for example.

The wiring board 20 is a space transformer that extends a distance between the proximal ends of the probes 10 to a distance between the wiring patterns 400 in the printed board 40 in plan view viewed from a direction normal to a main surface of the wiring board 20, for example. By using the space transformer for the wiring board 20, it is possible to electrically connect the proximal ends of the probes 10 corresponding to a distance between the signal terminals arranged on the object 2 to be inspected, to the wiring patterns 400 in the printed board 40 arranged at a distance larger than a distance between the proximal ends.

As shown in FIG. 1, the stiffener 50 may be laminated on the printed board 40. The stiffener 50 has higher stiffness than the printed board 40, and ensures the mechanical strength of the electrical connection apparatus 1 by preventing the printed board 40 from being bent. In addition, the stiffener 50 may be used as a support for fixing each component of the electrical connection apparatus 1. The stiffener 50 may be fixed to the printed board 40 using screws, for example.

The relay circuit 30 is connected to first wiring 201A and second wiring 202A, each of which is electrically connected to either one of first electrodes 21 different from each other. The relay circuit 30 shown in FIG. 1 is connected to the first wiring 201A and the second wiring 202A of the connecting wiring 200 arranged in the wiring board 20. The first wiring 201A is electrically connected to a first probe 101 of the plurality of probes 10. The second wiring 202A is electrically connected to a second probe 102 of the plurality of probes 10.

As shown in FIG. 2, the relay circuit 30 includes a common terminal 300, a first wiring terminal 301A connected to the first wiring 201A, a second wiring terminal 302A connected to the second wiring 202A, a first inspection terminal 301B, and a second inspection terminal 302B. The first inspection terminal 301B can be electrically connected to the inspection device via first inspection wiring 201B of the connecting wiring 200 in the wiring board 20 and a part of the wiring patterns 400 in the printed board 40. The second inspection terminal 302B can be electrically connected to the inspection device via second inspection wiring 202B of the connecting wiring 200 in the wiring board 20 and a part of the wiring patterns 400 in the printed board 40.

The relay circuit 30 selectively connects the first wiring terminal 301A to either the common terminal 300 or the first inspection terminal 301B. Further, the relay circuit 30 selectively connects the second wiring terminal 302A to either the common terminal 300 or the second inspection terminal 302B. Hereinafter, an operation of switching connection objects of the first wiring terminal 301A and the second wiring terminal 302A performed by the relay circuit 30 will also be referred to as a “switching operation”. The switching operation performed by the relay circuit 30 may be controlled using a control signal CS received by the relay circuit 30 from the inspection device.

The relay circuit 30 connects the second wiring terminal 302A to the common terminal 300 at the timing at which the first wiring terminal 301A is connected to the common terminal 300. A state in which the first wiring terminal 301A and the second wiring terminal 302A are connected to the common terminal 300 will be referred to as a “first connection state” below. Meanwhile, the relay circuit 30 connects the second wiring terminal 302A to the second inspection terminal 302B at the timing at which the first wiring terminal 301A is connected to the first inspection terminal 301B. A state in which the first wiring terminal 301A is connected to the first inspection terminal 301B, and the second wiring terminal 302A is connected to the second inspection terminal 302B will be referred to as a “second connection state” below.

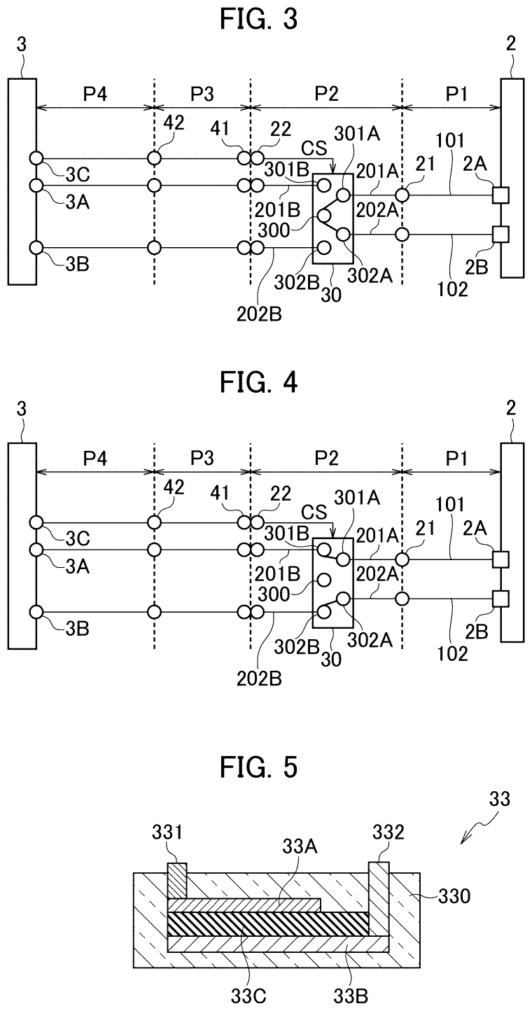

FIG. 3 shows a wiring path in the first connection state. As shown in FIG. 3, a wiring path between the object 2 to be inspected and the inspection device 3 is constituted by a first section P1 through a fourth section P4 (the same applies hereinafter). The first section P1 is a wiring path via the probes 10 of which tips are in contact with the signal terminals of the object 2 to be inspected. The second section P2 is a wiring path constituted by the connecting wiring 200 in the wiring board 20. The third section P3 is a wiring path constituted by the wiring patterns 400 in the printed board 40. The fourth section P4 is a wiring path from the printed board 40 to the inspection device 3.

As shown in FIG. 3, in the first connection state, the first probe 101 electrically connected to the first wiring 201A and the second probe 102 electrically connected to the second wiring 202A are electrically connected via the common terminal 300. That is, in the electrical connection apparatus 1, a loopback circuit can be constituted by the first probe 101 and the second probe 102 which are electrically connected to the common terminal 300 individually.

Two signal terminals of the object 2 to be inspected are electrically connected by means of the loopback circuit configured in the first connection state. FIG. 3 exemplifies a case where a first signal terminal 2A of the object 2 to be inspected contacted by the first probe 101, and a second signal terminal 2B of the object 2 to be inspected contacted by the second probe 102, are electrically connected via the common terminal 300. Suppose that the object 2 to be inspected is a receiving circuit, the first signal terminal 2A is an output terminal of the object 2 to be inspected, and the second signal terminal 2B is an input terminal of the object 2 to be inspected, for example. In the above case, a transmission test can be performed by returning an output from the object 2 to be inspected to an input. In other words, it is possible to test whether an output unit and an input unit of the object 2 to be inspected are functioning normally, even if there is no destination equipment for transmission. As an inspection in accordance with a jitter tolerance test performed for a receiving circuit, an output signal output from the first signal terminal 2A (output terminal) may be input to the second signal terminal 2B (input terminal) as an input signal to inspect whether a specified error rate is ensured, for example.

Meanwhile, as shown in FIG. 4, in the second connection state, the first probe 101 electrically connected to the first wiring 201A is electrically connected to the inspection device 3 via the wiring board 20 and the printed board 40. In other words, the first signal terminal 2A of the object 2 to be inspected is electrically connected to a first terminal 3A of the inspection device 3 via the electrical connection apparatus 1. Further, the second probe 102 electrically connected to the second wiring 202A is electrically connected to the inspection device 3 via the wiring board 20 and the printed board 40. In other words, the second signal terminal 2B of the object 2 to be inspected is electrically connected to a second terminal 3B of the inspection device 3 via the electrical connection apparatus 1.

As described above, in the second connection state, the signal terminals of the object 2 to be inspected are electrically connected to the terminals of the inspection device 3 via the relay circuit 30. In the second connection state, an electrical signal propagates between the inspection device 3 such as an IC tester and the object 2 to be inspected to measure characteristics of the object 2 to be inspected.

The common terminal 300 of the relay circuit 30 may include a capacitor which can be electrically connected to the first wiring 201A and the second wiring 202A. FIG. 5 shows an example of a capacitor 33 of the common terminal 300. The capacitor 33 may be a capacitor (hereinafter also referred to as a “process capacitor”) formed on a semiconductor substrate using a semiconductor manufacturing process. The capacitor 33 shown in FIG. 5 is obtained by forming, inside a semiconductor substrate 330, a laminated body in which a dielectric layer 33C is interposed between a first electrode layer 33A and a second electrode layer 33B. A first electrode terminal 331 connected to the first electrode layer 33A and a second electrode terminal 332 connected to the second electrode layer 33B are disposed on one main surface of the semiconductor substrate 330.

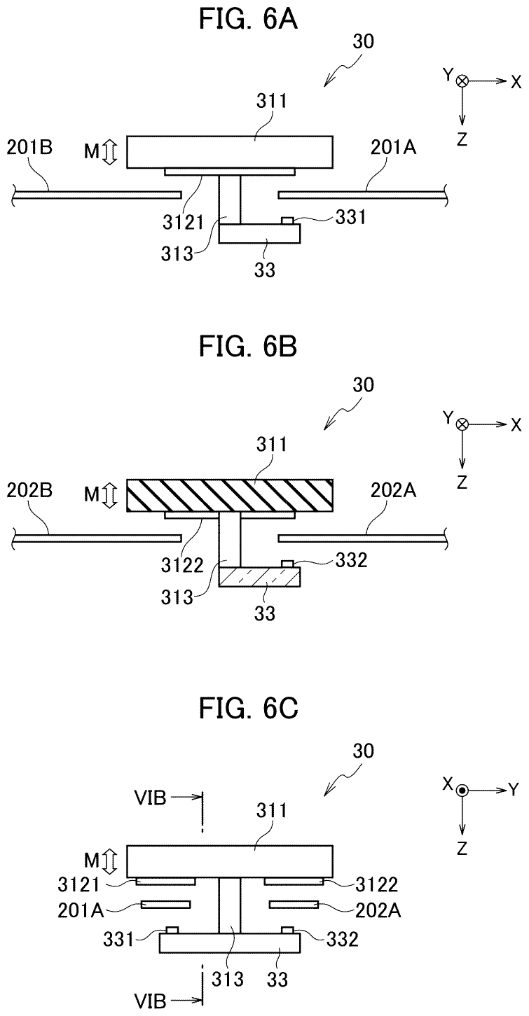

FIGS. 6A to 6C show examples of the configuration of the relay circuit 30 having the capacitor 33. FIG. 6A shows a position of the first electrode terminal 331 facing the first wiring 201A. FIG. 6B shows a position of the second electrode terminal 332 facing the second wiring 202A. In FIGS. 6A and 6B, a direction from an up side to a down side of the page space is defined as a Z direction, a direction which is from a right side to a left side of the page space and is perpendicular to the Z direction is defined as an X direction, and a direction which is from a front side to a back side of the page space and is perpendicular to the Z direction is defined as a Y direction. FIG. 6C shows a relative positional relationship between the first electrode terminal 331 and the second electrode terminal 332 as viewed from the X direction. FIG. 6B is a cross-sectional view which is taken along line VIB-VIB in FIG. 6C. In the following, a diagram as viewed from the X direction is defined as a front view, and a diagram as viewed from the Y direction is defined as a side view.

The relay circuit 30 shown in FIGS. 6A to 6C has a support portion 311 of which a main surface is parallel to an XY plane, first short-circuit wiring 3121 and second short-circuit wiring 3122 which are arranged on a main surface of the support portion 311 facing the Z direction, and a column portion 313 which has one end connected to the support portion 311 and extends in the Z direction. The support portion 311 has insulation, and the first short-circuit wiring 3121 and the second short-circuit wiring 3122 have conductivity. Both of the first short-circuit wiring 3121 and the second short-circuit wiring 3122 are arranged in parallel along the Y direction and extend in the X direction. In the following, when the first short-circuit wiring 3121 and the second short-circuit wiring 3122 are not limited, they are also collectively referred to as short-circuit wiring 312.

The capacitor 33 is connected to the other end of the column portion 313. The first electrode terminal 331 and the second electrode terminal 332 are arranged along the Y direction on a main surface of the capacitor 33 facing the support portion 311.

As shown in FIGS. 6A to 6C, the first wiring 201A and the second wiring 202A are located between the support portion 311 and the capacitor 33. The first wiring 201A and the second wiring 202A are arranged at the same XY plane level and the first short-circuit wiring 3121 and the second short-circuit wiring 3122 are arranged at the same XY plane level.

When viewed from the Z direction, the first electrode terminal 331 faces the first wiring 201A, and the second electrode terminal 332 faces the second wiring 202A. When viewed from the Z direction, the first short-circuit wiring 3121 faces the first wiring 201A and the first inspection wiring 201B. When viewed from the Z direction, the second short-circuit wiring 3122 faces the second wiring 202A and the second inspection wiring 202B.

The relay circuit 30 shown in FIGS. 6A to 6C is movable in an M direction along the Z direction relative to the first wiring 201A, the second wiring 202A, the first inspection wiring 201B, and the second inspection wiring 202B. The support portion 311 on which the short-circuit wiring 312 is arranged, the column portion 313, and the capacitor 33 move integrally. The relay circuit 30 moves in the Z direction between the first connection state and the second connection state in response to the control signal CS, for example.

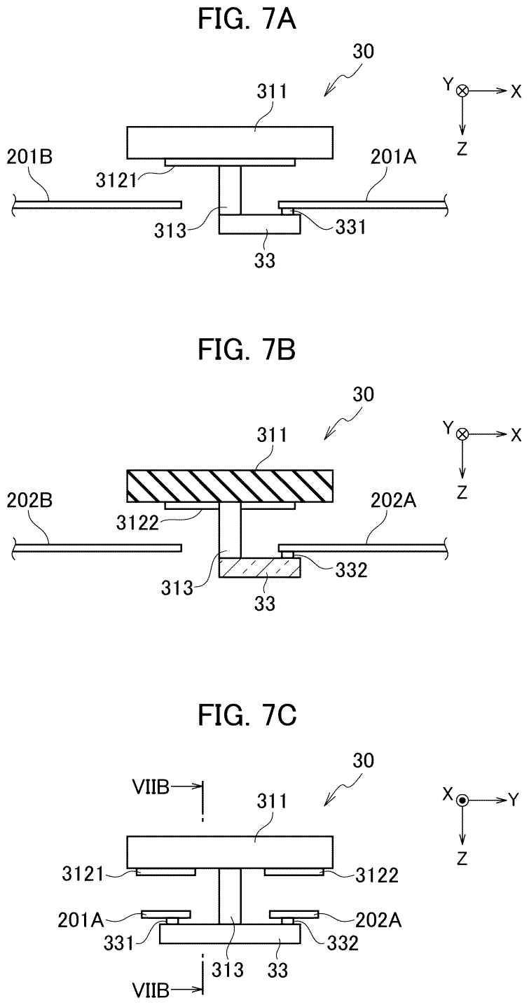

FIGS. 7A to 7C show examples of the first connection state of the relay circuit 30 shown in FIGS. 6A to 6C. FIG. 7B is a cross-sectional view which is taken along line VIIB-VIIB in FIG. 7C. The relay circuit 30 in the first connection state moves in a −Z direction compared to the relay circuit shown in FIGS. 6A to 6C. As a result, in the first connection state, the first electrode terminal 331 of the capacitor 33 is electrically connected to the first wiring 201A, and the second electrode terminal 332 is electrically connected to the second wiring 202A. In the first connection state, the first electrode terminal 331 corresponds to the first wiring terminal 301A, and the second electrode terminal 332 corresponds to the second wiring terminal 302A. Further, the capacitor 33 corresponds to the common terminal 300.

In the first connection state, the first signal terminal 2A and the second signal terminal 2B of the object 2 to be inspected are electrically connected via the capacitor 33. In other words, in the first connection state, a loopback circuit including the capacitor 33 is formed between the first signal terminal 2A and the second signal terminal 2B.

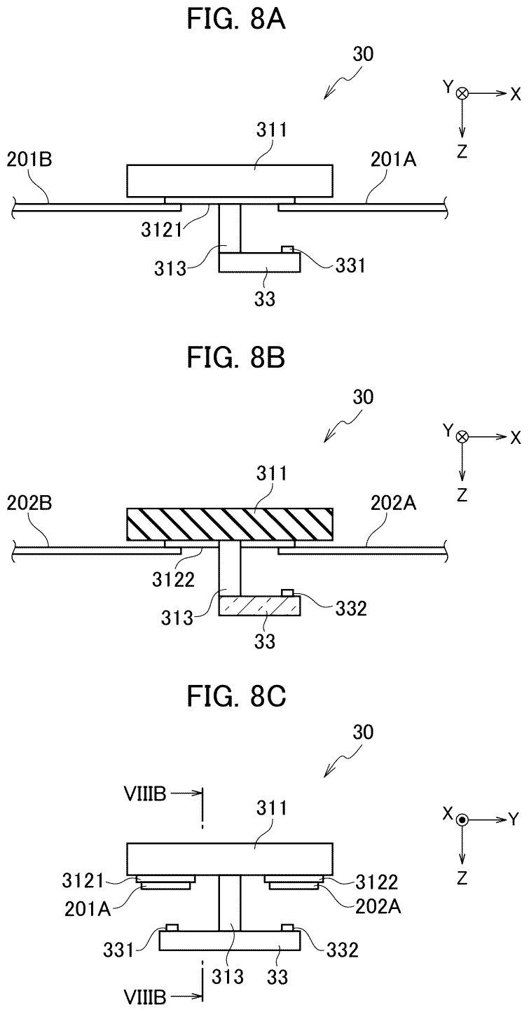

FIGS. 8A to 8C show examples of the second connection state of the relay circuit 30 shown in FIGS. 6A to 6C. FIG. 8B is a cross-sectional view which is taken along line VIIIB-VIIIB in FIG. 8C. The relay circuit 30 in the second connection state moves in the Z direction compared to the relay circuit shown in FIGS. 6A to 6C. As a result, in the second connection state, the first wiring 201A and the first inspection wiring 201B are connected to the first short-circuit wiring 3121. Further, the second wiring 202A and the second inspection wiring 202B are connected to the second short-circuit wiring 3122. That is, the first wiring 201A and the first inspection wiring 201B are electrically connected via the first short-circuit wiring 3121, and the second wiring 202A and the second inspection wiring 202B are electrically connected via the second short-circuit wiring 3122.

In the second connection state, a portion of the first short-circuit wiring 3121 connected to the first wiring 201A corresponds to the first wiring terminal 301A, and a portion of the first short-circuit wiring 3121 connected to the first inspection wiring 201B corresponds to the first inspection terminal 301B. Further, a portion of the second short-circuit wiring 3122 connected to the second wiring 202A corresponds to the second wiring terminal 302A, and a portion of the second short-circuit wiring 3122 connected to the second inspection wiring 202B corresponds to the second inspection terminal 302B.

In the second connection state, the first signal terminal 2A and the second signal terminal 2B of the object 2 to be inspected are electrically connected to the first terminal 3A and the second terminal 3B of the inspection device 3, respectively. As a result, in the second connection state, an electrical signal propagates between the inspection device 3 and the object 2 to be inspected to measure characteristics of the object 2 to be inspected.

As described above, the common terminal 300, the first wiring terminal 301A, the second wiring terminal 302A, the first inspection terminal 301B, and the second inspection terminal 302B are integrally formed as the relay circuit 30. Therefore, the relay circuit 30 has a simple circuit structure and a short signal path therein. Furthermore, the external size of the relay circuit 30 having an integrated circuit structure can be reduced. The relay circuit 30 can be reduced in size by integrally forming the relay circuit 30 using a Micro Electro Mechanical Systems (MEMS) process, for example.

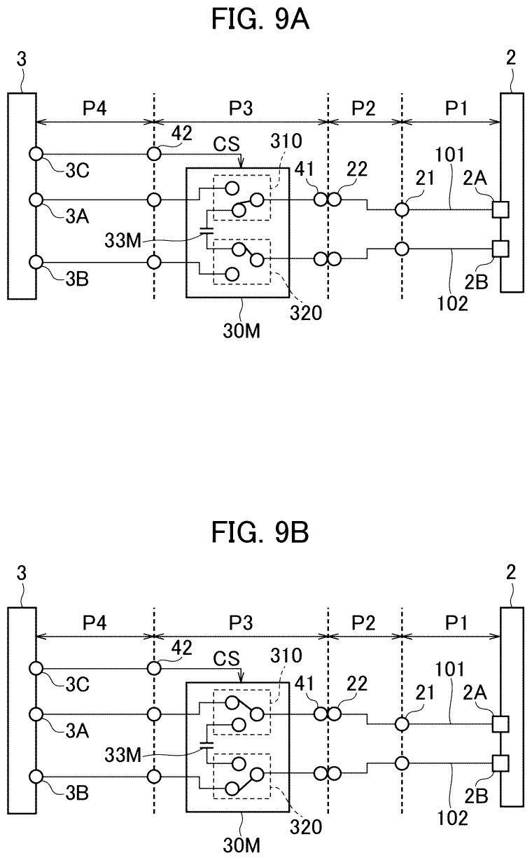

Meanwhile, configurations similar to those in the first connection state and the second connection state can be implemented using a relay circuit of a comparative example including two relays and external capacitance 33M (hereinafter also referred to as a “comparison relay circuit 30M”) as shown in FIGS. 9A and 9B. The comparison relay circuit 30M controlled using the control signal CS electrically connects the first signal terminal 2A of the object 2 to be inspected to either the first terminal 3A of the inspection device 3 or the external capacitance 33M by means of a first relay 310 therein. Further, the comparison relay circuit 30M electrically connects the second signal terminal 2B of the object 2 to be inspected to either the second terminal 3B of the inspection device 3 or the external capacitance 33M by means of a second relay 320 therein. That is, as shown in FIG. 9A, the comparison relay circuit 30M electrically connects the first signal terminal 2A of the object 2 to be inspected to one terminal of the external capacitance 33M, and electrically connects the second signal terminal 2B of the object 2 to be inspected to the other terminal of the external capacitance 33M. Alternatively, as shown in FIG. 9B, the comparison relay circuit 30M electrically connects the first signal terminal 2A of the object 2 to be inspected to the first terminal 3A of the inspection device 3, and electrically connects the second signal terminal 2B of the object 2 to be inspected to the second terminal 3B of the inspection device 3.

However, it is difficult to reduce the size of the comparison relay circuit 30M. That is, the comparison relay circuit 30M has a structure which is more complicated than that of the relay circuit 30 and the external size thereof is larger because the comparison relay circuit 30M has the two relays and external capacitance therein. Therefore, a signal path of the comparison relay circuit 30M is longer than that of the relay circuit 30, and large signal loss and noise are caused.

Further, by reducing the size of the relay circuit 30, the degree of freedom of an arrangement position of the relay circuit 30 is increased. The relay circuit 30 can be arranged on the wiring board 20 which is closer to the probes 10 than the printed board 40, for example. By reducing a distance between the probes 10 and the relay circuit 30, it is possible to reduce the length of wiring for connecting the probes 10 and the relay circuit 30. As a result, when high-frequency characteristics of the object 2 to be inspected are measured using a loopback circuit, it is possible to suppress the occurrence of the loss of a signal propagating through the wiring and noise.

As described above, the electrical connection apparatus 1 according to the first embodiment including the relay circuit 30 can reduce the loss and noise of a loopback circuit.

The relay circuit 30 may perform the switching operation in response to the control signal CS from the inspection device, for example. Due to the relay circuit 30 being configured to receive the control signal CS from the inspection device, the loopback circuit can be configured at an arbitrary timing during a series of inspections of the object 2 to be inspected. Wiring between the relay circuit 30 and the inspection device, through which the control signal CS propagates may be formed on the wiring board 20 and the printed board 40, for example. Alternatively, the switching operation of the relay circuit 30 may be performed manually.

### Second Embodiment

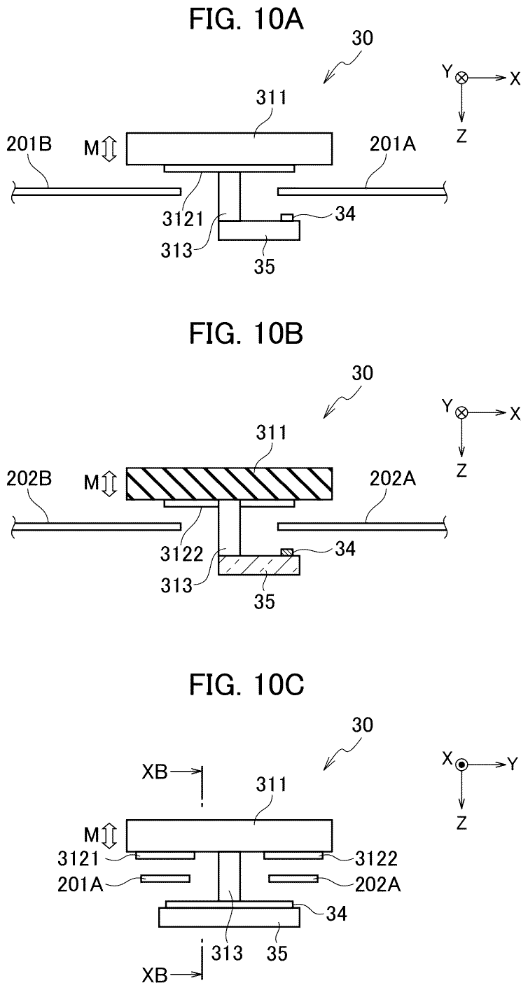

In an electrical connection apparatus 1 according to a second embodiment, as shown in FIGS. 10A to 10C, a support substrate 35 with coupled wiring 34 arranged on a main surface thereof, instead of a capacitor 33, is connected to the other end of a column portion 313 having one end connected to a support portion 311. The coupled wiring 34 is made of a conductive material and is arranged on the main surface of the support substrate 35 facing the support portion 311. The coupled wiring 34 faces first wiring 201A and second wiring 202A. The difference between the second embodiment and the first embodiment resides in that a relay circuit 30 of the electrical connection apparatus 1 according to the second embodiment includes the coupled wiring 34 instead of a capacitor 33. Other configurations of the electrical connection apparatus 1 according to the second embodiment are similar to those of the first embodiment shown in FIG. 1.

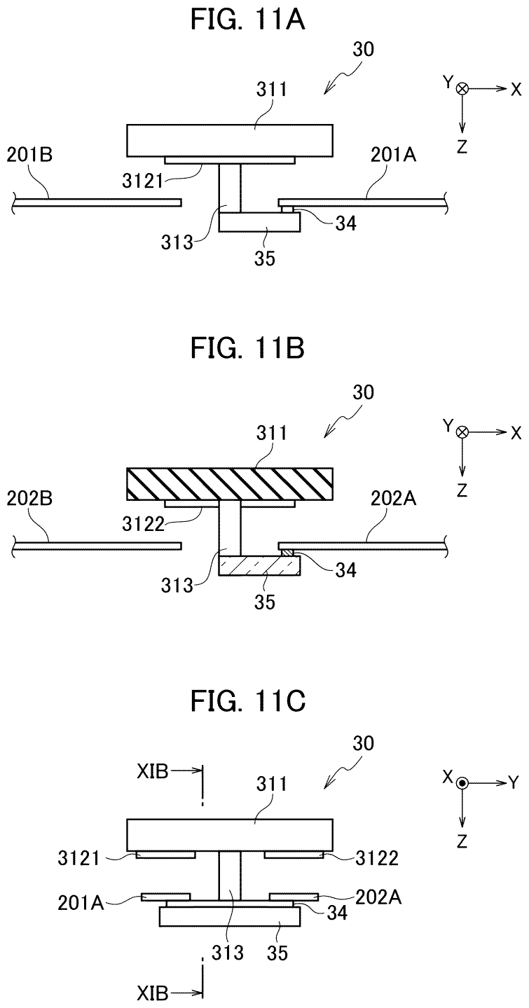

In the first connection state, as shown in FIGS. 11A to 11C, the relay circuit 30 moves in the −Z direction from the position of the relay circuit shown in FIGS. 10A to 10C. This connects the first wiring 201A and the second wiring 202A to the coupled wiring 34. As a result, the first wiring 201A and the second wiring 202A are electrically connected via the coupled wiring 34.

Therefore, in the first connection state, a first signal terminal 2A and a second signal terminal 2B of an object 2 to be inspected are electrically connected via the coupled wiring 34. In other words, in the first connection state, a loopback circuit is constituted in which the first signal terminal 2A and the second signal terminal 2B are connected in series.

In the electrical connection apparatus 1 according to the second embodiment also, a configuration of the second connection state is similar to that described with reference to FIGS. 8A to 8C. That is, the first signal terminal 2A and the second signal terminal 2B of the object 2 to be inspected are electrically connected to a first terminal 3A and a second terminal 3B of an inspection device 3 via short-circuit wiring 312. Therefore, a description of the second connection state will be omitted.

When a protective element with capacitance is connected to an input/output terminal of the object 2 to be inspected, a measurement waveform becomes distorted, for example. For this reason, the inspection device may measure the object 2 to be inspected while the protective element is not connected. In this case, the capacitor 33 included in the relay circuit 30 of the electrical connection apparatus 1 according to the first embodiment functions instead of the protective element.

Meanwhile, if the protective element is not connected to the object 2 to be inspected, or if capacitance of the protective element is not a measurement problem, the relay circuit 30 may not include the capacitor 33 as in the electrical connection apparatus 1 according to the second embodiment. Due to the relay circuit 30 not including the capacitor 33, a circuit structure of the relay circuit 30 can be further simplified and a signal path therein can be shortened. Other configurations of the electrical connection apparatus 1 according to the second embodiment are substantially the same as those of the first embodiment, and therefore a duplicate description thereof will be omitted.

### Other Embodiments

Although embodiments of the present invention have been described above, the discussion and drawings forming part of this disclosure should not be construed as limiting the invention. Various alternative embodiments, examples, and operational techniques will be apparent to those skilled in the art from this disclosure.

A case where the relay circuit 30 is disposed on the wiring board 20 has been exemplified above, for example. However, the relay circuit 30 may be disposed at any position in the electrical connection apparatus 1. Since the relay circuit 30 of the electrical connection apparatus 1 is reduced in size, the degree of freedom of an arrangement position of the relay circuit 30 is high. Therefore, the relay circuit 30 may be disposed on the printed board 40, for example. However, shorter wiring for connecting the probes 10 and the relay circuit 30 is preferable in terms of reduction in the loss of a signal propagating to the relay circuit 30 and noise.

Further, although a case where the number of relay circuit 30 is one has been exemplified, the electrical connection apparatus 1 may include a plurality of relay circuits 30. According to the electrical connection apparatus 1 including the plurality of relay circuits 30, a loopback circuit can be configured for any two signal terminals of the object 2 to be inspected, or a plurality of loopback circuits can be configured simultaneously.

Although a case where the relay circuit 30 includes the capacitor 33 has been exemplified above, an element such as an inductor or a resistor element may be arranged in the relay circuit 30 in addition to the capacitor 33. A passive element included in the relay circuit 30 may be selected to have an impedance match of a loopback circuit, for example. In this way, the electrical connection apparatus 1 can optionally select an element to be inserted into a loopback circuit in accordance with inspection contents of the object 2 to be inspected.

FIG. 1 has shown a case where the electrical connection apparatus 1 having the relay circuit 30 includes the probes 10 in contact with the object 2 to be inspected. It is possible to measure electrical characteristics of an object 2 to be inspected not separated from a wafer or an object 2 to be inspected which is converted into a chip using the electrical connection apparatus 1 shown in FIG. 1, for example. Meanwhile, the relay circuit 30 may be arranged in an electrical connection apparatus including a test socket, to support the measurement of electrical characteristics of the object 2 to be inspected performed in a state where the object 2 to be inspected is mounted in a package or the like. The test socket having a terminal for inspection, connected to an external terminal of the package in which the object 2 to be inspected is mounted, may be arranged on the wiring board 20 instead of the probes 10 of the electrical connection apparatus 1 shown in FIG. 1, for example. For signal terminals of the object 2 to be inspected mounted in the package, it is possible to constitute a loopback circuit via the external terminal of the package and the terminal for inspection of the test socket by connecting the test socket and the package. The electrical connection apparatus including the test socket can also switch between the first connection state and the second connection state in the same way as the electrical connection apparatus 1 including the probes 10 described above.

Further, the switching operation of the relay circuit 30 may be controlled by the object 2 to be inspected. A semiconductor device serving as the object 2 to be inspected outputs the control signal CS for controlling the switching operation to the relay circuit 30 and may have a self-diagnosis function of performing measurement using a loopback circuit, for example. In other words, the electrical connection apparatus 1 and the object 2 to be inspected may be configured such that the relay circuit 30 can receive the control signal CS from the object 2 to be inspected, and the object 2 to be inspected may control an operation of the relay circuit 30. By means of the control signal CS, the relay circuit 30 selectively connects the first wiring terminal 301A to either the common terminal 300 or the first inspection terminal 301B, and selectively connects the second wiring terminal 302A to either the common terminal 300 or the second inspection terminal 302B. An inspection circuit incorporated in the object 2 to be inspected may transmit the control signal CS to the relay circuit 30 via a terminal for inspection of the electrical connection apparatus 1 to constitute a loopback circuit, and the object 2 to be inspected may perform self-diagnosis, for example. As described above, even with the object 2 to be inspected in which an inspection device is incorporated, the loss and noise of a loopback circuit can be reduced.

In this way, it is needless to say that the present invention includes various embodiments not described above. Therefore, the technical scope of the present invention is defined only by matters specified in the invention that are within the scope of claims appropriate from the above description.

What is claimed is:

1. An electrical connection apparatus used for an inspection of an object to be inspected by an inspection device, the electrical connection apparatus comprising:
a plurality of terminals for inspection in contact with the object to be inspected;
a wiring board including a plurality of first electrodes each of which is electrically connected to any one of the terminals for inspection, a plurality of connecting wiring each of which is connected to any one of the first electrodes, and a plurality of second electrodes each of which is electrically connected to any one of the first electrodes via the connecting wiring; and
a relay circuit connected to first wiring and second wiring, each of which is electrically connected to either one of first electrodes different from each other, wherein
the relay circuit includes:
a common terminal;
a first wiring terminal connected to the first wiring;
a second wiring terminal connected to the second wiring; and
a first inspection terminal and a second inspection terminal that can be electrically connected to the inspection device,
the relay circuit selectively connects the first wiring terminal to either the common terminal or the first inspection terminal, and
the relay circuit selectively connects the second wiring terminal to either the common terminal or the second inspection terminal.

2. The electrical connection apparatus according to claim 1, wherein
a loopback circuit can be configured that includes a first terminal for inspection of the terminals for inspection electrically connected to the common terminal, and a second terminal for inspection of the terminals for inspection electrically connected to the common terminal, and electrically connects two signal terminals of the object to be inspected.

3. The electrical connection apparatus according to claim 1, wherein
the common terminal, the first wiring terminal, the second wiring terminal, the first inspection terminal, and the second inspection terminal are integrally formed.

4. The electrical connection apparatus according to claim 1, wherein
the common terminal includes a capacitor,
a first electrode terminal of the capacitor can be electrically connected to the first wiring, and
a second electrode terminal of the capacitor can be electrically connected to the second wiring.

5. The electrical connection apparatus according to claim 1, wherein
the relay circuit is disposed on the wiring board, and
the connecting wiring includes the first wiring and the second wiring.

6. The electrical connection apparatus according to claim 5, wherein
the first inspection terminal and the second inspection terminal are electrically connected to the second electrodes.

7. The electrical connection apparatus according to claim 5, further comprising:
a printed board that is laminated on the wiring board and includes wiring patterns for electrically connecting the second electrodes and the inspection device.

8. The electrical connection apparatus according to claim 7, wherein
the wiring board is a space transformer that extends a distance between the terminals for inspection to a distance between the wiring patterns in plan view viewed from a direction normal to a main surface of the wiring board.

9. The electrical connection apparatus according to claim 1, wherein
the relay circuit can receive, from the inspection device, a control signal for causing the relay circuit to selectively connect the first wiring terminal to either the common terminal or the first inspection terminal and selectively connect the second wiring terminal to either the common terminal or the second inspection terminal.

10. The electrical connection apparatus according to claim 1, wherein
the relay circuit can receive, from the object to be inspected, a control signal for causing the relay circuit to selectively connect the first wiring terminal to either the common terminal or the first inspection terminal and selectively connect the second wiring terminal to either the common terminal or the second inspection terminal.

11. The electrical connection apparatus according to claim 1, wherein
each of the terminals for inspection is a probe having one end connected to the wiring board and the other end in contact with a signal terminal of the object to be inspected.

12. The electrical connection apparatus according to claim 1, wherein
the terminals for inspection are disposed in a test socket connected to an external terminal of a package in which the object to be inspected is mounted.

13. A relay circuit comprising:
a common terminal;
a first wiring terminal and a second wiring terminal; and
a first inspection terminal and a second inspection terminal, wherein
the relay circuit selectively connects the first wiring terminal to either the common terminal or the first inspection terminal,
the relay circuit selectively connects the second wiring terminal to either the common terminal or the second inspection terminal, and
the common terminal, the first wiring terminal, the second wiring terminal, the first inspection terminal, and the second inspection terminal are integrally formed.

14. The relay circuit according to claim 13, wherein
the common terminal, the first wiring terminal, the second wiring terminal, the first inspection terminal, and the second inspection terminal are integrally formed using an MEMS process.

15. The relay circuit according to claim 13, wherein
the common terminal includes a capacitor,
a first electrode terminal of the capacitor can be electrically connected to the first wiring terminal, and
a second electrode terminal of the capacitor can be electrically connected to the second wiring terminal.
